(19) United States
(12) Patent Application Publication
(10) Pub. No.: US 2025/0118584 A1
(43) Pub. Date: Apr. 10, 2025

(54) SUBSTRATE TRANSFER DEVICE, NOTCH POSITION CORRECTION METHOD, SUBSTRATE TRANSFER METHOD, AND STORAGE MEDIUM

(71) Applicant: ASM IP Holding B.V., Almere (NL)

(72) Inventor: Masashi Nakano, Tokyo (JP)

(21) Appl. No.: 18/905,937

(22) Filed: Oct. 3, 2024

Related U.S. Application Data
(60) Provisional application No. 63/542,896, filed on Oct. 6, 2023.

(51) Int. Cl. H01L 21/677; H01L 21/687

(52) U.S. Cl. CPC H01L 21/67745; H01L 21/68707

(57) ABSTRACT

Examples of a substrate transfer device includes a load lock chamber (LLC), a first wafer handling chamber (WHC), a first transfer robot fixed at a first attachment position in the first WHC, a pass through chamber (PTC) that is in contact with the first WHC, a substrate stage provided in the PTC, a second WHC that is in contact with the PTC, and a second transfer robot fixed at a second attachment position in the second WHC. A first angle that is an angle formed by a first virtual line that connects the first attachment position and the second attachment position and a second virtual line that connects the first attachment position and the substrate stage is equal to a second angle that is an angle formed by the first virtual line and a third virtual line that connects the second attachment position and the substrate stage.

### CROSS-REFERENCE TO RELATED APPLICATION(S)

This Application claims the benefit of U.S. Provisional Application 63/542,896 filed on Oct. 6, 2023, the entire contents of which are incorporated herein by reference.

### FIELD OF INVENTION

Examples are described which relate to a substrate transfer device, a notch position correction method, a substrate transfer method, and a storage medium.

### BACKGROUND OF THE DISCLOSURE

There is a substrate storage case in which a plurality of substrates are stored. Examples of such a substrate storage case include an FOUP. The substrate storage case is loaded on a mechanism called load port. On the load port, a door of the substrate storage case is opened, and a substrate is taken out from the substrate storage case by a substrate transfer robot and provided to a substrate processing device. The load port is sometimes referred to as an FOUP opener. The substrate subjected to predetermined processing at the substrate processing device is returned to the substrate storage case by the substrate transfer robot.

The substrate has a notch or orientation flat, and in the present disclosure, a notch or orientation flat is referred to as a “notch portion” or simply a “notch”. If positions of notch portions of all the substrates are aligned when all the substrates are returned to the substrate storage case after being subjected to the processing, the processing can proceed to next processing without the need to align the positions of the notch portions by an aligner. However, there has been a problem that the positions of the notch portions of all the substrates stored in the substrate storage case are not aligned depending on a configuration of the substrate processing device, and a notch aligner is required before the next processing.

### SUMMARY OF THE DISCLOSURE

Some examples described herein may address the above-described problems. Some examples described herein may provide a substrate transfer device capable of aligning positions of notch portions of substrates, a notch position correction method, a substrate transfer method and a storage medium.

In some examples, a substrate transfer device includes a load lock chamber (LLC), a first wafer handling chamber (WHC) that is in contact with the LLC, a first transfer robot fixed at a first attachment position in the first WHC, a pass through chamber (PTC) that is in contact with the first WHC, a substrate stage provided in the PTC, a second WHC that is in contact with the PTC, and a second transfer robot fixed at a second attachment position in the second WHC, wherein a first angle that is an angle formed by a first virtual line that connects the first attachment position and the second attachment position and a second virtual line that connects the first attachment position and the substrate stage is equal to a second angle that is an angle formed by the first virtual line and a third virtual line that connects the second attachment position and the substrate stage.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 is a plan view of a substrate transfer device according to an embodiment;

FIG. 2 is a plan view illustrating a configuration example of the first WHC, the PTC and the second WHC;

FIG. 3 is a table indicating relationships between substrate transfer routes and notch positions;

FIG. 4 is a view illustrating adjustment of the position of the notch portion by operation of the transfer robot;

FIG. 5A indicates substrate transfer for notch rotation;

FIG. 5B indicates another substrate transfer for notch rotation;

FIG. 6 is a table indicating relationships between the substrate transfer routes and the notch positions;

FIG. 7 is a table indicating the substrate transfer routes and positional change amounts of the notch portion according to an offset approach;

FIG. 8A is a diagram illustrating an example of the controller;

FIG. 8B is a diagram illustrating another example of the controller; and

FIG. 9 is a view illustrating a device configuration example of a transfer system.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

### Embodiment

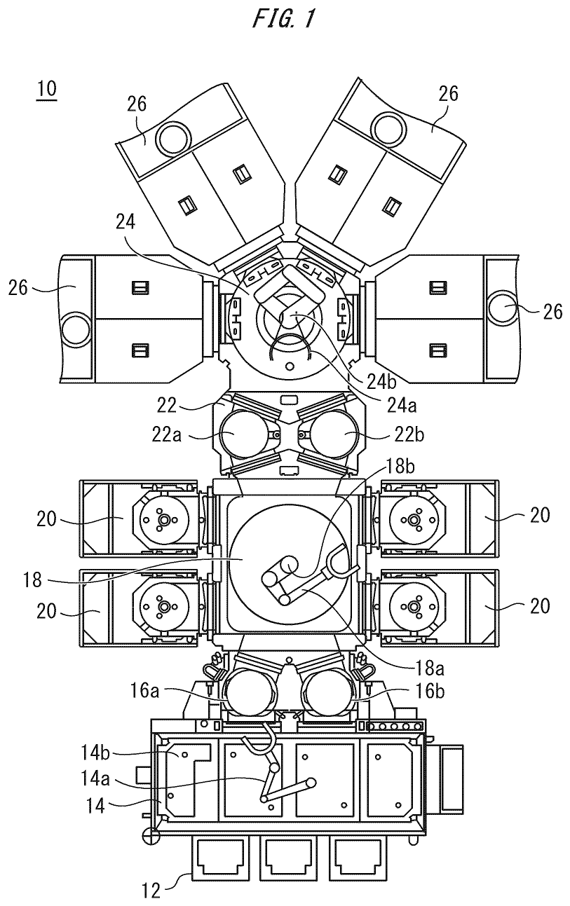

FIG. 1 is a plan view of a substrate transfer device according to an embodiment. The substrate transfer device 10 includes a load port 12. An equipment front end module (EFEM) 14 is in contact with the load port 12. According to one example, a front end robot (FERB) 14a and an aligner 14b are provided in the EFEM 14. The FERB 14a is a wafer transfer mechanism for transferring a substrate as a non-limiting example. The FERB 14a, which is, for example, a single-arm or multi-arm robot, supports, vacuum attracts or electrostatically attracts each substrate by an arm located at an end of the FERB 14a.

The aligner 14b is configured to adjust a notch position of the substrate to a predetermined position. According to one example, the aligner 14b rotates the substrate by a rotation mechanism, detects a position of the notch portion by a notch sensor, or the like, stores the position or moves the notch portion to the designated position. The aligner 14b is sometimes referred to as an alignment device.

A load lock chamber (LLC) 16a and an LLC 16b are in contact with the EFEM 14. According to one example, the LLC 16a includes a plurality of slots on which wafers are to be loaded and holds a plurality of wafers in a non-contact manner and in a superimposed manner, and the LLC 16b has the same configuration as the configuration of the LLC 16a. A first wafer handling chamber (WHC) 18 is in contact with the LLC 16a and LLC 16b. A first transfer robot 18a is fixed at a first attachment position 18b in the first WHC 18. The first transfer robot 18a has, for example, a fixing end at the first attachment position 18b and has an arm at an end on an opposite side of the fixing end. According to one example, the first transfer robot 18a, which is a single-arm or multi-arm robot, supports, vacuum attracts or electrostatically attracts each substrate by an arm. The first attachment position 18b is, for example, located substantially at the center of the first WHC 18 in plan view.

Four front side substrate processing chambers 20 are in contact with a side surface of the first WHC 18. Each of the four front side substrate processing chambers 20 can be configured to perform arbitrary processing, for example, pre-cleaning processing, film formation, etching, and film reformulation on one substrate. The pre-cleaning processing is, for example, processing for removing a natural oxide film of the substrate.

A pass through chamber (PTC) 22 is in contact with the first WHC 18. For example, two substrate stages are provided in the PTC 22. FIG. 1 illustrates a first substrate stage 22a and a second substrate stage 22b.

A second WHC 24 is in contact with the PTC 22. A second transfer robot 24a is fixed at a second attachment position 24b in the second WHC 24. The second transfer robot 24a, for example, has a fixing end at the second attachment position 24b and has an arm at an end on an opposite side of the fixing end. According to one example, the second transfer robot 24a, which is a single-arm or multi-arm robot, supports, vacuum attracts or electrostatically attracts each substrate by an arm. The second attachment position 24b is, for example, located substantially at the center of the second WHC 24 in plan view.

Four back side substrate processing chambers 26 are in contact with a side surface of the second WHC 24. Each of the four back side substrate processing chambers 26 can be configured to perform arbitrary processing such as, for example, pre-cleaning processing, film formation, etching and film reformulation on one substrate.

The FERB 14a is configured to be able to take a substrate in/out to/from the load port 12, the aligner 14b and the LLC 16a and LLC 16b. The first transfer robot 18a is configured to be able to take a substrate in/out to/from the LLC 16a and LLC 16b, the four front side substrate processing chambers 20 and the PTC 22. The second transfer robot 24a is configured to be able to take a substrate in/out to/from the PTC 22 and the four back side substrate processing chamber 26.

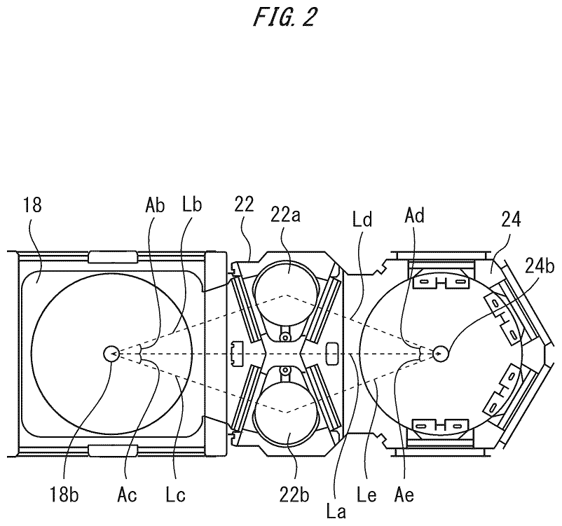

FIG. 2 is a plan view illustrating a configuration example of the first WHC 18, the PTC 22 and the second WHC 24. In FIG. 2, a first virtual line La that connects the first attachment position 18b and the second attachment position 24b is drawn with a dashed line in plan view. Further, a second virtual line Lb that connects the first attachment position 18b and the first substrate stage 22a and a second virtual line Lc that connects the first attachment position 18b and the second substrate stage 22b are drawn with dashed lines. The second virtual line Lb extends to the center of the first substrate stage 22a, and the second virtual line Lc extends to the center of the second substrate stage 22b. Further, a third virtual line Ld that connects the second attachment position 24b and the first substrate stage 22a, and a third virtual line Le that connects the second attachment position 24b and the second substrate stage 22b are drawn with dashed lines. The third virtual line Ld extends to the center of the first substrate stage 22a, and the third virtual line Le extends to the center of the second substrate stage 22b.

According to one example, a first angle Ab that is an angle formed by the first virtual line La and the second virtual line Lb is equal to a second angle Ad that is an angle formed by the first virtual line La and the third virtual line Ld. Further, a first angle Ac that is an angle formed by the first virtual line La and the second virtual line Lc is equal to a second angle Ae that is an angle formed by the first virtual line La and the third virtual line Le. For example, the first angles Ab and Ac, and the second angles Ad and Ae are 10°, 12°, 15°, 20°, 30° or 40°. According to another example, the first angles Ab and Ac, and the second angles Ad and Ae are one of divisors of 360.

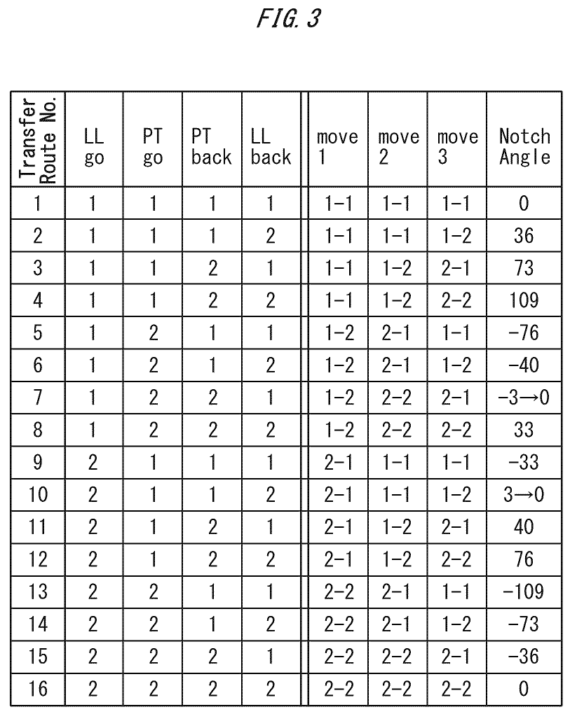

FIG. 3 is a table indicating relationships between substrate transfer routes and notch positions. First, a notch position of a substate is detected by a sensor of the aligner 14b in the EFEM 14, and the result is memorized in a controller. Then, the substrate is loaded on one of the LLC 16a or 16b. In this event, a position of the notch portion is located at a desired position. A route of the substrate until the substrate is returned to the LLC again after the substrate is provided to the LLC is summarized in FIG. 3. FIG. 3 indicates 16 patterns of substrate transfer routes, and details of each transfer route. In a field of LLgo, which of two LLC 16a and LLC 16b, the substrate passes through when the substrate moves from the EFEM 14 to the first WHC 18 is indicated. If 1 is indicated in the field of LLgo, the substrate moves from the LLC 16a to the first WHC 18, and if 2 is indicated in the field of LLgo, the substrate moves from the LLC 16b to the first WHC 18.

In a field of PTgo in FIG. 3, which of the first substrate stage 22a and the second substrate stage 22b, the substrate passes through when the substrate moves from the first WHC 18 to the second WHC 24 is indicated. If 1 is indicated in the field of PTgo, the substrate moves from the first substrate stage 22a to the second WHC 24, and if 2 is indicated in the field of PTgo, the substrate moves from the second substrate stage 22b to the second WHC 24.

In a field of PTback in FIG. 3, to which of the first substrate stage 22a and the second substrate stage 22b, the substrate provided to the second WHC 24 is returned is indicated. If 1 is indicated in the field of PTback, the substrate is returned to the first substrate stage 22a, and if 2 is indicated in the field of PTback, the substrate is returned to the second substrate stage 22b.

In a field of LLback in FIG. 3, to which of the LLC 16a and the LLC 16b, the substrate returned to the PTC 22 from the second WHC 24 is returned is indicated. If 1 is indicated in the field of LLback, the substrate is returned to the LLC 16a from the PTC 22, and if 2 is indicated in the field of LLback, the substrate is returned from the PTC 22 to the LLC 16b.

In a field of move 1 in FIG. 3, from which LLC to which stage of PTC, the substrate moves is indicated. If 1-1 is indicated in the field of move 1, the substrate moves from the LLC 16a to the first substrate stage 22a, if 1-2 is indicated, the substrate moves from the LLC 16a to the second substrate stage 22b, if 2-1 is indicated, the substrate moves from the LLC 16b to the first substrate stage 22a, and if 2-2 is indicated, the substrate moves from the LLC 16b to the second substrate stage 22b.

In a field of move 2 in FIG. 3, from which substrate stage the substrate exits to the second WHC 24, and to which substrate stage the substrate is returned are indicated. If 1-1 is indicated in the field of move 2, the substate exits from the first substrate stage 22a to the second WHC 24 and moves to the first substrate stage 22a, if 1-2 is indicated, the substrate exists from the first substrate stage 22a to the second WHC 24 and moves to the second substrate stage 22b, if 2-1 is indicated, the substrate exits from the second substrate stage 22b to the second WHC 24 and moves to the first substrate stage 22a, and if 2-2 is indicated, the substrate exits from the second substrate stage 22b to the second WHC 24 and moves to the second substrate stage 22b.

In a field of move 3 in FIG. 3, from which substrate stage the substrate is returned to the first WHC 18, and to which LLC the substrate is returned are indicated. If 1-1 is indicated in the field of move 3, the substrate exits from the first substrate stage 22a to the first WHC 18 and moves to the LLC 16a, if 1-2 is indicated, the substrate exits from the first substrate stage 22a to the first WHC 18 and moves to the LLC 16b, if 2-1 is indicated, the substrate exits from the second substrate stage 22b to the first WHC 18 and moves to the LLC 16a, and if 2-2 is indicated, the substrate exits from the second substrate stage 22b to the first WHC 18 and moves to the LLC 16b.

At an arbitrary timing on the substrate transfer route so far, the substrate is transferred to the front side substrate processing chamber 20 and the back side substrate processing chamber 26 and subjected to predetermined processing. For example, in midstream of move 1, the substrate can be discharged to the front side substrate processing chamber 20, and the substrate can be received from the front side substrate processing chamber 20. For example, in midstream of move 2, the substrate can be discharged to the back side substrate processing chamber 26, and the substrate can be received from the back side substrate processing chamber 26. For example, in midstream of move 3, the substrate can be discharged to the front side substrate processing chamber 20, and the substrate can be received from the front side substrate processing chamber 20. FIG. 3 explains the substrate transfer routes while focusing on the LLC and the PTC, and thus, such transfer to the processing chamber is omitted.

FIG. 3 indicates on a rightmost column, a difference between a position of the notch portion of the substrate when the substrate is provided from the EFEM 14 to the LLC, and the position of the notch portion when the substrate is returned to the LLC after movement of move 1-3. The difference in the position of the notch portion is represented by a rotational component, that is, an angle. According to FIG. 3, among 16 patterns of the transfer routes, a positional change of the notch portion in association with a series of transfer processing can be avoided if the transfer route is a transfer route number 1 or 16. In a case of the transfer route number 1 or 16, the positional change of the notch portion is prevented regardless of values of the first angles Ab and Ac and the second angles Ad and Ae defined with reference to FIG. 2. In other words, by limiting the transfer route to the transfer route number 1 or 16and prohibiting other transfer routes, all the substrates can be stored in the substrate storage case while the positions of the notch portions are aligned. However, in this case, the transfer routes are too limited, which causes delay and sacrifices productivity.

By making the first angle Ab equal to the second angle Ad in FIG. 2 and making the first angle Ac equal to the second angle Ae, positional changes of the notch portion in the transfer route numbers 7 and 10 in FIG. 3 can be made 0. On the other hand, if a difference between the first angle Ab and the second angle Ad is 1.5° and a difference between the first angle Ac and the second angle Ae is 1.5°, a positional change of the notch portion in the transfer route number 7 becomes −3°, and a positional change of the notch portion in the transfer route number 10 becomes 3°. In this manner, by making the first angle Ab equal to the second angle Ad and making the first angle Ac equal to the second angle Ae, the transfer route numbers 7 and 10 can be utilized in addition to the transfer route numbers 1 and 16, so that it is possible to improve throughput.

For example, the substrate transfer device 10 includes a controller that controls the first transfer robot 18a and the second transfer robot 24a, and the controller limits the substrate transfer routes to the following four routes.

Route that utilizes the first stage (LLC 16a) and the first substrate stage 22a when the substrate reaches the second WHC 24 from the LLC and utilizes the first substrate stage 22a and the first stage (LLC 16a) when the substrate is returned to the LLC from the second WHC 24

Route that utilizes the first stage (LLC 16a) and the second substrate stage 22b when the substrate reaches the second WHC 24 from the LLC and utilizes the second substrate stage 22b and the first stage (LLC 16a) when the substrate is returned to the LLC from the second WHC 24

Route that utilizes the second stage (LLC 16b) and the first substrate stage 22a when the substrate reaches the second WHC 24 from the LLC and utilizes the first substrate stage 22a and the second stage (LLC 16b) when the substrate is returned to the LLC from the second WHC 24

Route that utilizes the second stage (LLC 16b) and the second substrate stage 22b when the substrate reaches the second WHC 24 from the LLC and utilizes the second substrate stage 22b and the second stage (LLC 16b) when the substrate is returned to the LLC from the second WHC 24

This limits the substrate transfer routes to the transfer route numbers 1, 7, 10 and 16 in FIG. 3 and can improve throughput to some extent while avoiding a positional change of the notch portion.

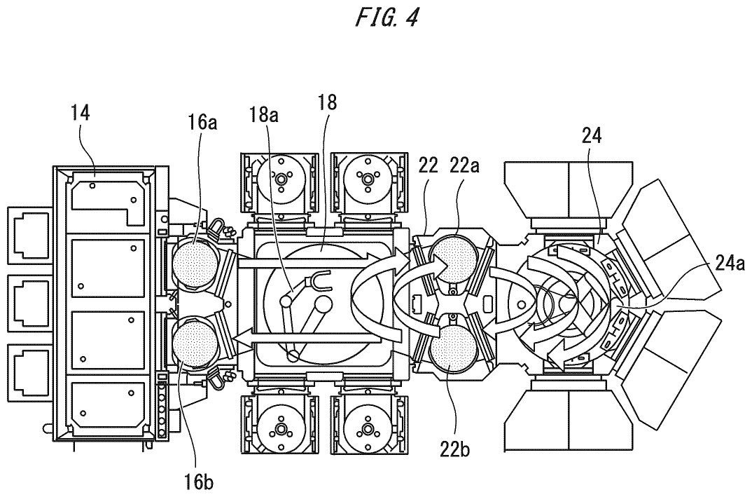

FIG. 4 is a view illustrating adjustment of the position of the notch portion by operation of the transfer robot. A substrate transfer system in FIG. 4 changes the position of the notch of the substrate in a rotation direction by repeating a plurality of times, processing of returning the substrate from the first substrate stage 22a to the first substrate stage 22a by way of the second substrate stage 22b or processing of returning the substrate from the second substrate stage 22b to the second substrate stage 22b by way of the first substrate stage 22a. A semicircular arrow in FIG. 4 indicates such movement of the substrate in the rotation direction. Through such rotation processing of the substrate, the position of the notch portion can be adjusted to the predetermined position. In other words, it is possible to adjust the position of the notch portion to the predetermined position by adding the above-described rotation processing while employing a transfer route through which the position of the notch portion cannot be returned to the predetermined position. This contributes to increase in the number of transfer routes.

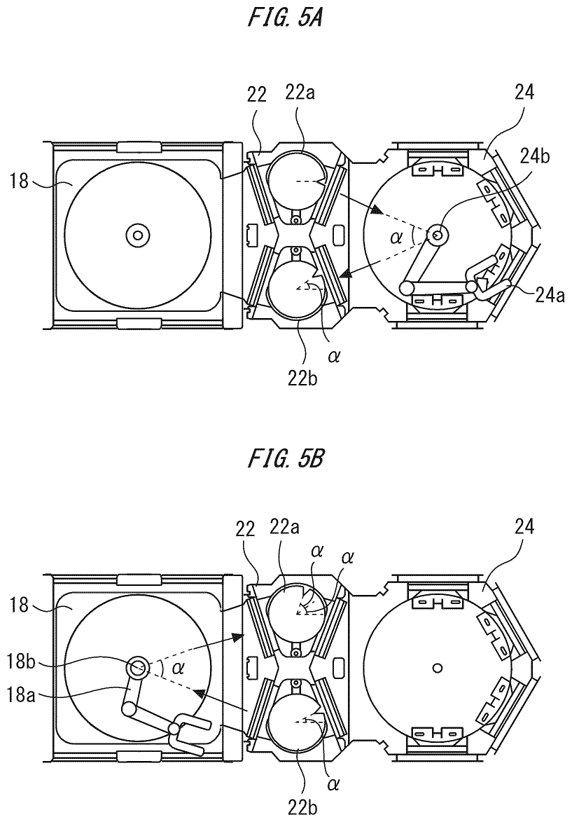

FIG. 5 is a view illustrating an example of such movement of the substrate in the rotation direction. FIG. 5A indicates that a notch of the substrate loaded on the first substrate stage 22a is located in a rightward direction. The substrate located in the PTC is moved to the second substrate stage 22b by the transfer robot (second transfer robot 24a) located in the wafer handling chamber (second WHC 24) that is in contact with the PTC so as to change the position of the notch of the substrate in the rotation direction. In this manner, if the substrate is moved to the second substrate stage 22b by the second transfer robot 24a, the substrate rotates by a rotation angle α of the second transfer robot 24a. This results in moving the notch of the substrate on the second substrate stage 22b by the angle α in a counterclockwise direction.

FIG. 5B indicates that a notch of the substrate loaded on the second substrate stage 22b is located at a position rotated by a in the counterclockwise direction from the rightward direction. This substrate is moved to the first substrate stage 22a by the opposite-side transfer robot (first transfer robot 18a) located in the opposite-side WHC (first WHC 18) that is in contact with the PTC on an opposite side of the WHC (second WHC 24) so as to change the position of the notch of the substrate in the rotation direction. By this means, the substrate rotates by the rotation angle a of the first transfer robot 18a. This results in moving the notch of the substrate by the angle α in the counterclockwise direction. Use of terms of the transfer robot and the opposite-side transfer robot intends to indicate that positional relationships between these transfer robots and the LLCs are not particularly limited.

By alternately repeating movement of the substrate using the transfer robot and the opposite-side transfer robot, the notch position of the substrate can be corrected to the predetermined position. According to one example, such rotation processing of the substrate can be achieved by the controller controlling the first transfer robot 18a and the second transfer robot 24a (or the transfer robot and the opposite-side transfer robot). Further, the substrate whose notch position is corrected using such a method is moved to the load lock chamber by the transfer robot or the opposite-side transfer robot without changing the position of the notch in the rotation direction. This can make the positions of the notch portions of the substrates uniform to the predetermined position.

In a platform in which the first angle Ab and the second angle Ad defined in FIG. 2 are made uniform to one of divisors of 360 and the first angle Ac and the second angle Ae are made uniform to one of divisors of 360, rotation processing of the notch portion described with reference to FIGS. 4 and 5 can be performed. For example, if α in FIGS. 5A and 5B is set at 10°, 15°, 20°, 30° or 40°, the position of the notch portion can be changed in the rotation direction by 20°, 30°, 40°, 60° or 80° through one-time rotation processing of the substrate. By returning the substrates to the LLC after adjusting the positions of the notch portions to the predetermined position through such rotation processing, the notch positions can be made uniform. In other words, the positions of the notch portions can be aligned while making some new transfer routes available in addition to the four transfer routes in FIG. 3.

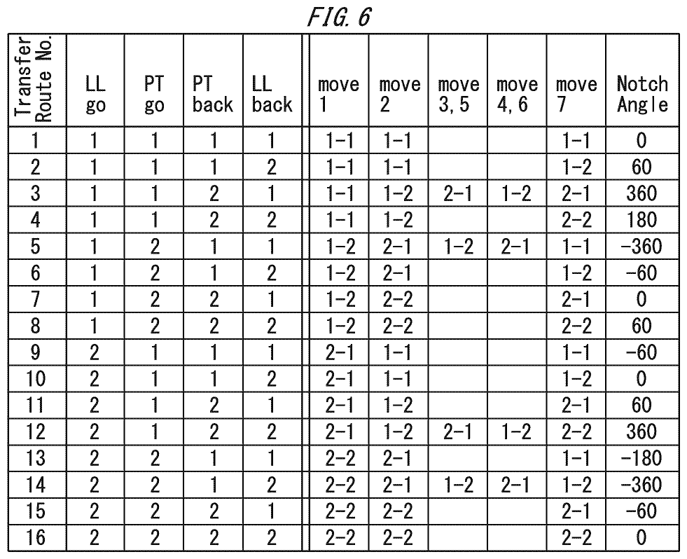

FIG. 6 is a table indicating relationships between the substrate transfer routes and the notch positions. In FIG. 6, moves 3 to 6 mean rotation processing of the substrate described in FIG. 5. According to the transfer routes 1, 7, 10 and 16 in which a value in the rightmost column in FIG. 6 is 0, the positions of the notch portions can be aligned before and after transfer without performing rotation processing of the substrates. Further, according to the transfer routes 3, 5, 12 and 14 in which the value in the rightmost column is 360 or −360, the positions of the notch portions can be made the same as the positions of the notch portions through the transfer routes 1, 7, 10 and 16 by the substrates being rotated one revolution through move 3, 4 and rotated another one revolution through move 5, 6. Thus, in this example, the positions of the notch portions can be aligned while improving throughput by making the transfer routes 1, 7, 10 and 16 and the transfer routes 3, 5, 12 and 14 available.

Unlike with the examples so far, the notch positions of the substrates when the substrates are returned to the LLC can be made uniform by offsetting the positions of the notch portions by rotating the substrates before transfer of the substrates is started. Such a substrate transfer method includes, for example, the following processing.

First processing: calculate a rotation direction of the notch position of the substrate and an angular change amount of the notch position assumed by the substrate being transferred through a scheduled transfer route that passes through the pass through chamber

Second processing: rotate the substrate by an amount equal to the angular change amount in an opposite direction of the rotation direction

Third processing: transfer the substrate through the scheduled transfer route

According to one example, the scheduled transfer route includes the load lock chamber LLCs 16a and 16b, the first WHC 18, the PTC 22 and the second WHC 24.

As a result of the processing proceeding in order of the first processing, the second processing and the third processing, the positions of the notch portions when the substrates are returned to the LLC can be made uniform whichever transfer route the substrates pass through. By storing a plurality of substrates transferred through the scheduled transfer route in the substrate case without changing the angle in the rotation direction of the notch, alignment of the substrates in the next process can be omitted.

The first processing is processing of calculating a change of the position of the notch portion in a case where the substrate is transferred through the scheduled transfer route without offsetting the notch portion. Specifically, a transfer pattern of the substrate determined by a device called a sequencer that controls movement of the substrate is acquired, and a misalignment of the notch portion occurring by the transfer pattern is calculated. The misalignment of the notch portion is defined by, for example, the rotation direction of the notch position and the angular change amount of the notch position.

In the second processing, the offset is applied as described above by, for example, rotating the substrate by a notch aligner in the EFEM. In the third processing, the substrate is transferred through the scheduled transfer route. The scheduled transfer route is not particularly limited as long as the transfer route includes the PTC and two WHCs that sandwich the PTC. According to one example, while a plurality of substrates rotate depending on the transfer routes by passing through the PTC and the two WHCs, the rotation is cancelled out by the above-described offset, and thereby the positions of the notch portions of all the substrates are eventually aligned.

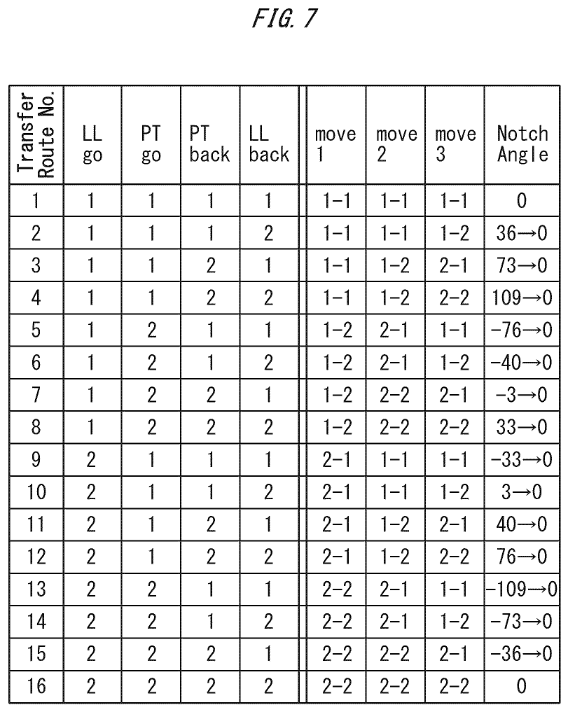

FIG. 7 is a table indicating the substrate transfer routes and positional change amounts of the notch portion in such an offset approach. In a case where the substrate is transferred on the platform in FIG. 1, there are 16 patterns of transfer routes. For example, while an angular change amount of the notch portion assumed through the transfer route of the transfer route number 2 is 36°, by applying an offset of −36° in advance, the angle of the notch portion when the substrate is returned to the LLC can be made 0°, that is a desired angle. By applying an offset in a similar manner also for the transfer route numbers 3 to 15, the angles of the notch portions when the substrates are returned to the LLC can be made 0°. It is therefore possible to align the positions of the notch portions while making all the transfer routes available.

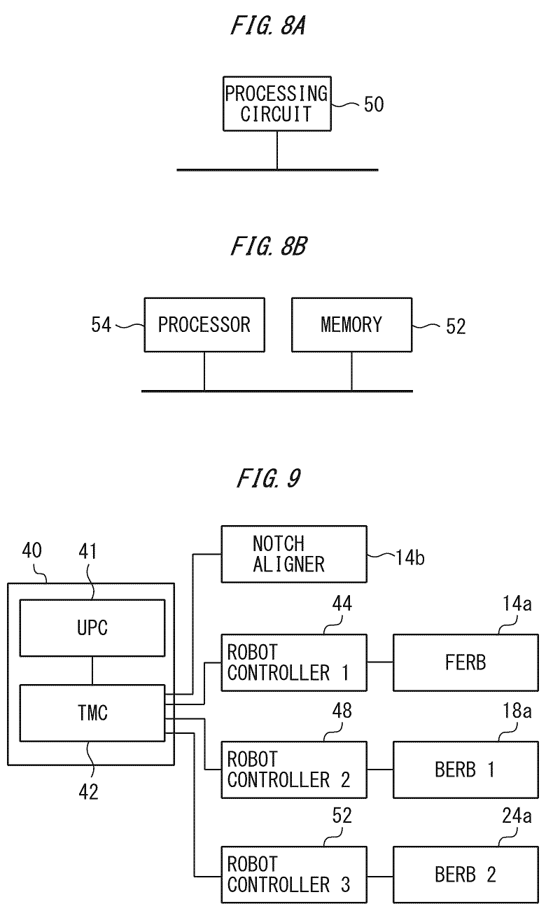

FIG. 8A and 8B are diagrams illustrating an example of the controller. The controller controls devices related to substrate transfer to achieve above-described substrate transfer. In the example in FIG. 1, the FERB 14a, the aligner 14b, the first transfer robot 18a and the second transfer robot 24a are controlled by the controller. The controller includes a processing circuit 50. The above-described functions are implemented by the processing circuit 50. In other words, the processing circuit 50 issues a command for transferring the substrate as per the predetermined transfer route to the FERB 14a, the aligner 14b, the first transfer robot 18a and the second transfer robot 24a. Such a transfer route can include the rotation processing, for example, as illustrated in FIGS. 4 and 5. According to another example, the processing circuit 50 issues a command for executing the first to the third processing described above which is characterized by an offset, to the substrate transfer device.

The processing circuit 50 may be provided as dedicated hardware (dedicated circuit) or may be a CPU (a central processing unit, a processing device, an arithmetic device, a microprocessor, a microcomputer, a processor, or a DSP) which executes a program stored in a memory. If the processing circuit 50 is dedicated hardware, the processing circuit may be, for example, a single circuit, a composite circuit, a programmed processor, a parallel programmed processor, an ASIC, an FPGA, or combinations thereof.

FIG. 8B shows a configuration example of the controller in the case where the processing circuit is a CPU. In this case, each of the functions of the controller is realized by software or a combination of software and firmware. The software or the firmware is described as a program, and is stored in a memory 52. A processor 54 reads out and executes the program stored in the memory 52, and thereby realizes each of the functions. In other words, the controller includes the memory 52 that stores the program which results in executing each of the above-described steps, when the program is executed by the processing circuit. It can also be said that these programs cause the computer to execute procedures and methods of substrate transfer. Here, the memory corresponds to, for example, a nonvolatile or volatile semiconductor memory such as a RAM, a ROM, a flash memory, an EPROM and an EEPROM; a magnetic disk; a flexible disk; an optical disk; a compact disk; a mini disk; or a DVD. As a matter of course, it is also acceptable to realize a part of each of the above functions by hardware, and realize a part of the functions by software or firmware.

The above-described functions are implemented by the processor executing the program stored in the memory or processing by a dedicated circuit. According to one example, the following program is recorded in a computer-readable storage medium. The program causes a computer to execute a step of taking out one substrate from a first side surface of a pass through chamber (PTC) having two stages and moving the substrate to another stage of the PTC and a step of taking out the moved substrate from a second side surface of the PTC and moving the substrate to another stage of the PTC.

FIG. 9 is a view illustrating a device configuration example of a transfer system. A control unit 40 includes a unique platform controller (UPC) 41. The UPC 41 is a portion that schedules substrate processing, gives a command to execute the substrate processing, and the like. Data regarding a configuration of the substrate processing device, a recipe that specifies processing of the substrate and information regarding environment settings such as settings of turning on/off an alarm and language settings are stored in the UPC 41. For example, the processing chamber 20 and the processing chamber 26 are connected to the UPC 41.

A transfer module controller (TMC) 42 is connected to the UPC 41. The aligner 14b, and robot controllers 44, 48 and 52 are connected to the TMC 42. The robot controllers 44, 48 and 51 are, for example, respectively provided in lower portions or upper portions of the FERB 14a, the first transfer robot 18a and the second transfer robot 24a. The TMC 42 receives a command from the UPC 41 and controls the notch aligner 14b and the robot controllers 44, 48 and 52. While not illustrated, a load lock chamber, a gate valve, and the like, are also to be controlled by the TMC 42.

1. A substrate transfer device comprising:
a load lock chamber (LLC);
a first wafer handling chamber (WHC) that is in contact with the LLC;
a first transfer robot fixed at a first attachment position in the first WHC;
a pass through chamber (PTC) that is in contact with the first WHC;
a substrate stage provided in the PTC;
a second WHC that is in contact with the PTC; and
a second transfer robot fixed at a second attachment position in the second WHC,
wherein a first angle that is an angle formed by a first virtual line that connects the first attachment position and the second attachment position and a second virtual line that connects the first attachment position and the substrate stage is equal to a second angle that is an angle formed by the first virtual line and a third virtual line that connects the second attachment position and the substrate stage.

2. The substrate transfer device according to claim 1, wherein the first angle and the second angle are 10°, 12°, 15°, 20°, 30° or 40°.

3. The substrate transfer device according to claim 1, wherein the first angle and the second angle are one of divisors of 360.

4. The substrate transfer device according to claim 1, further comprising:
an EFEM that is in contact with the load lock chamber;
a load port that is in contact with the EFEM; and
an aligner provided in the EFEM and configured to adjust a notch position of a substrate to a predetermined position.

5. The substrate transfer device according to claim 1, wherein the substrate stage includes a first substrate stage and a second substrate stage.

6. The substrate transfer device according to claim 1, further comprising:
a front side substrate processing chamber that is in contact with the first WHC and provided for processing one substrate; and
a back side substrate processing chamber that is in contact with the second WHC and provided for processing one substrate.

7. The substrate transfer device according to claim 5, further comprising:
a controller configured to control the first transfer robot and the second transfer robot to limit a transfer route of a substrate to
a route that utilizes a first stage and the first substrate stage when the substrate reaches the second WHC from the LLC and utilizes the first substrate stage and the first stage when the substrate is returned to the LLC from the second WHC,
a route that utilizes the first stage and the second substrate stage when the substrate reaches the second WHC from the LLC and utilizes the second substrate stage and the first stage when the substrate is returned to the LLC from the second WHC,
a route that utilizes a second stage and the first substrate stage when the substrate reaches the second WHC from the LLC and utilizes the first substrate stage and the second stage when the substrate is returned to the LLC from the second WHC, or
a route that utilizes the second stage and the second substrate stage when the substrate reaches the second WHC from the LLC and utilizes the second substrate stage and the second stage when the substrate is returned to the LLC from the second WHC.

8. The substrate transfer device according to claim 5, further comprising:
a controller configured to control the first transfer robot and the second transfer robot to change a position of a notch of a substrate in a rotation direction by repeating a plurality of times, processing of returning the substrate from the first substrate stage to the first substrate stage by way of the second substrate stage or processing of returning the substrate from the second substrate stage to the second substrate stage by way of the first substrate stage.

9. A notch position correction method of correcting a notch position of a substrate to a predetermined position by alternately repeating:
moving the substrate loaded on a first substrate stage in a pass through chamber (PTC) to a second substrate stage in the PTC by a transfer robot located in a wafer handling chamber (WHC) that is in contact with the PTC to change a position of a notch of the substrate in a rotation direction; and
moving the substrate loaded on the second substrate stage to the first substrate stage by an opposite-side transfer robot in an opposite-side WHC that is in contact with the PTC on an opposite side of the WHC to change the position of the notch of the substrate in the rotation direction.

10. The notch position correction method according to claim 9, further comprising:
moving the substrate whose notch position is corrected to a load lock chamber by the transfer robot or the opposite-side transfer robot without changing the position of the notch in the rotation direction.

11. A substrate transfer method comprising in this order:
calculating a rotation direction of a notch position of a substrate and an angular change amount of the notch position assumed by the substrate being transferred through a scheduled transfer route that passes through a pass through chamber;
rotating the substrate by an amount equal to the angular change amount in an opposite direction of the rotation direction; and
transferring the substrate through the scheduled transfer route.

12. The substrate transfer method according to claim 11,
wherein the scheduled transfer route includes a load lock chamber, a first wafer handling chamber, the pass through chamber and a second wafer handling chamber.

13. The substrate transfer method according to claim 11, further comprising:
storing a plurality of substrates transferred through the scheduled transfer route in a substrate case without changing a rotation direction angle of a notch.

14. A computer-readable storage medium in which a program is recorded,
the program causing a computer to execute:
a step of taking out one substrate from a first side surface of a pass through chamber (PTC) having two stages and moving the substrate to another stage in the PTC; and
a step of taking out the moved substrate from a second side surface of the PTC and moving the substrate to another stage in the PTC.
